(19) United States
(12) Patent Application Publication
(10) Pub. No.: US 2006/0066352 A1
(43) Pub. Date: Mar. 30, 2006

(54) Low-voltage, low-skew differential transmitter

(76) Inventors: Bradley Kendall Davis, Fort Collins, CO (US); Raymond Albert Jansons, Waltham, MA (US); Robert Harris Woodside, Leominster, MA (US)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/957,139

(22) Filed: Sep. 30, 2004

(51) Int. Cl. H03K 19/0175

(52) U.S. Cl. 326/86

(57) ABSTRACT

A differential transmitter uses an H-bridge driver with upper and lower current paths switched in opposite phases. Switching occurs at the lowest level of each column of the H-bridge driver, thereby allowing the use of thin-gate transistors for high speed. One or more transistors in each column are provided to assure consistent performance across a wide range of PVT variations, and to provide the required short-circuit, ESD, and latch-up protection. A scaled copy of a column of the H-bridge driver provides replica biasing to effect the required voltage shift from core to I/O voltage levels.

This invention relates to the field of electronic circuits, and in particular to a low-voltage differential signal (LVDS) transmitter with low skew and low power consumption, that is suitable for operation across a frequency range from DC through multiple GigaHertz.

Differential signals are commonly used in electronic circuits and systems. The use of differential signals provides the opportunity to apply noise-canceling techniques. When the difference between two signals is used to determine the logic value associated with the information being communicated by the two signals, any noise that is common to both signals is cancelled/eliminated. The use of differential signaling typically requires complementary symmetry between the pair of differential signals, including coincident switching, so that the difference signal traverses between logic levels quickly, minimizing the time that the difference signal is in an ambiguous and/or potentially erroneous state. An offset of switching time between the pair of differential signals is termed “skew”, and the time required for each signal in the pair to change state is termed “transition time”. Low-skew and low-transition-time circuits are preferred for optimal differential signal processing, particularly at high speeds.

Differential signaling is particularly effective for transmitting signals between remote transmitters and receivers. In such an application, the differential receiver is designed to receive a potentially noisy and attenuated signal and to provide a substantially noise-free signal that is suitable for driving subsequent logic gates. To optimize the receiver's ability to effect this noisy to noise-free transformation, the transmitter is designed to provide a low-skew signal that is properly matched to the impedance of the transmission line to the receiver, and is at the proper common-mode voltage with the proper differential voltage swing.

LVDS signalling is commonly used for communicating information between integrated circuit (IC) chips, which may be on different printed circuit (PC) boards. In such applications, the LVDS devices must be designed to provide at least some short circuit, electrostatic discharge (ESD), and latch-up protection, particularly if these devices are being offered as components for use by third party designers, such as components in a standard-cell library or other design system. For maximum usability and marketability, the LVDS devices should should operate across a wide frequency range, including DC (static) operation, and should consume minimal power. The devices should also provide consistent performance across a wide range of process, voltage, and temperature (PVT) variations.

For maximum operational speed, a minimum span between logic voltage levels are used, because the operational speed is usually constrained by the transition time between logic voltage levels. However, larger spans between logic voltage levels improve the reliability of communications, because noise has less relative effect on larger signals. Typically, the voltage levels used within an integrated circuit are substantially lower than the voltages used for IC-to-IC communications, due to the higher noise levels and/or the greater attenuation of a communicated signal as it travels from IC to IC. Thus, a typical LVDS transmitter must provide a voltage-level shift from the within-IC, or “core” voltage levels, to the external, or “I/O” (input/output) voltage levels.

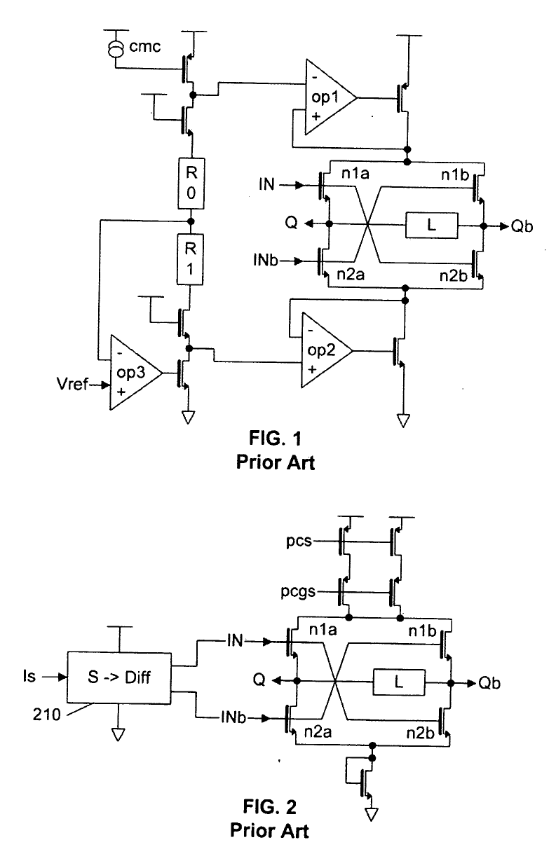

U.S. Pat. No. 6,111,431, “LVDS DRIVER FOR BACKPLANE APPLICATIONS”, issued 29 Aug. 2000 to Estrada and incorporated by reference herein, teaches a differential transmitter as illustrated in FIG. 1. Depending upon the state of the differential input signals IN and INb, n-channel transistors n1a-n2b or n1b-n2a are turned on, thereby determining the direction of current flow through load L, and thereby the relative voltages of differential output voltages Q and Qb. This circuit employs “replica biasing”, wherein the bias levels that are set on the left column of devices are replicated to the devices in the right column, via the operational amplifiers op1 and op2, thereby effecting the required voltage level shift from core to I/O voltage levels. Because of the relatively high voltage levels, switching devices n1a, n1b, n2a, n2b are required to be thick-gate devices, which consume more power than thin-gate devices, and limit the maximum speed of this transmitter. The use of single-channel devices n1a, n1b, n2a, n2b in the switching paths provide for consistent performance across a wide range of PVT variations.

U.S. Pat. No. 5,959,472, “DRIVER CIRCUIT DEVICE”, issued 28 Sep. 1999 to Nagamatsu et al. and incorporated by reference herein, teaches a differential transmitter with a converter 210 that converts a single-sided signal to a differential signal, as illustrated in FIG. 2. The upper p-channel transistors control the common-mode voltage and differential current via a common-mode feedback loop (not illustrated). Thick-gate n-channel devices are used to effect the switching, as in U.S. Pat. No. 6,111,431, above. Because the switching occurs at the I/O voltage levels, the converter 210 must be operated at the I/O voltage levels, thereby consuming more power than a converter that operates at the lower core voltage levels.

An object of this invention is to provide a low-power, low-skew, high-speed differential transmitter. Another object of this invention is to provide a low-power, low skew, high-speed differential transmitter with consistent performance across a wide range of PVT variations. Another object of this invention is to provide a low-power, low-skew, high-speed differential transmitter with short-circuit, ESD, and latch-up protection.

These objects and others are achieved by a differential transmitter that uses an H-bridge driver with upper and lower current paths switched in opposite phases. Switching occurs at the lowest level of each column of the H-bridge driver, thereby allowing the use of thin-gate transistors for high speed. One or more transistors in each column are provided to assure consistent performance across a wide range of PVT variations, and to provide the required short-circuit, ESD, and latch-up protection. A scaled copy of a column of the H-bridge driver provides replica biasing to effect the required voltage shift from core to I/O voltage levels.

The drawings are included for illustrative purposes and are not intended to limit the scope of the invention. In the drawings:

FIG. 1 illustrates an example schematic of a prior art differential transmitter that uses replica biasing to effect a voltage shift from core to I/O voltage levels.

FIG. 2 illustrates an example schematic of a prior art differential transmitter that includes a single-ended to differential signal converter.

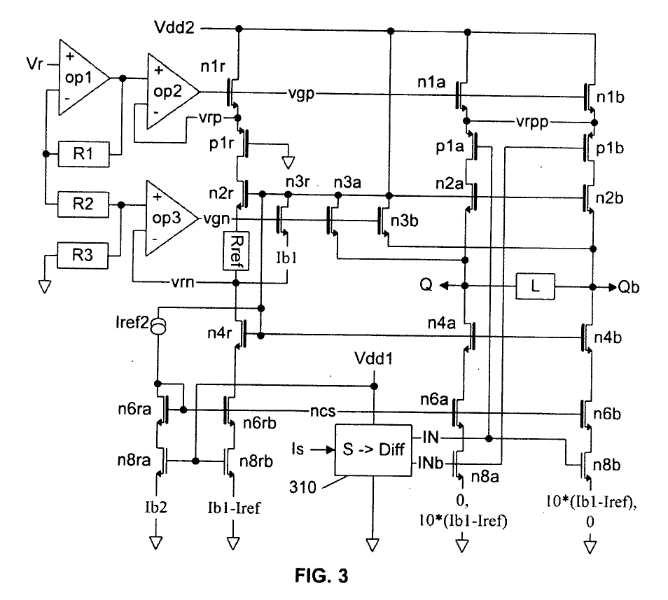

FIG. 3 illustrates an example schematic of a differential transmitter in accordance with this invention.

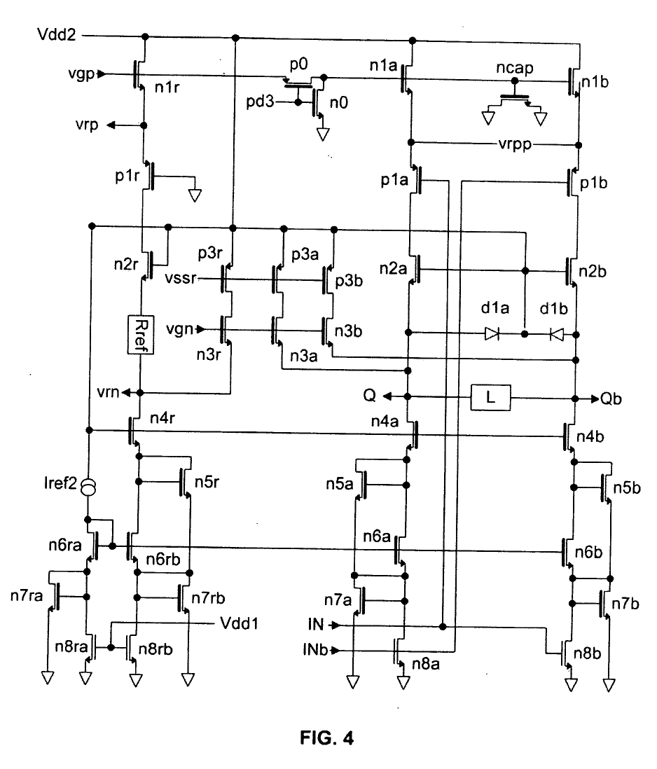

FIG. 4 illustrates an example schematic of a differential transmitter with short-circuit and ESD protection in accordance with this invention.

FIG. 3 illustrates an example schematic of a differential transmitter in accordance with this invention. Transistor devices p1a, n2a, n4a, n6a, n8a form one column of an H-bridge, and identical devices p1b, n2b, n4b, n6b, n8b for the other column. A load L bridges the columns, forming the H-bridge. Differential input signals IN and INb control the switching devices n8a, n8b and p1a, p1b. Depending upon the state of the differential input signals IN and INb, transistors p1a-n8b or p1b-n8a are turned on, thereby determining the direction of current flow through load L, and thereby the relative voltages of differential output voltages Q and Qb.

Note that transistors n8a, n8b are connected directly to the supply ground potential, and thus are efficiently driven at the core logic levels, herein defined as 0 and Vdd1. The transistors p1a, p1b are also directly driven from core logic levels as well, via the proper control of the voltage vrpp by operational amplifier op2, discussed further below. Thus, the circuitry that provides the differential input signals IN and INb, including, for example, a differential converter 310, can be operated at the core logic levels, thereby conserving power consumption and maximizing speed. Copending U.S. patent application “LOW-SKEW SINGLE-ENDED TO DIFFERENTIAL CONVERTER”, Ser. No. ______, filed ______, for Brad Davis, Attorney Docket US03.0368, teaches a converter 310 that includes a cross-coupled output latch that provides a low-skew output with rapid transients, and is incorporated by reference herein.

Because devices n8a, n8b are connected directly to the supply ground potential, minimum length thin-gate devices can be used, which greatly reduces the power (f*CgS*V²) required to drive these devices, compared to devices that are driven at the I/O voltage levels. Additionally, parasitic switching capacitance is minimized via the use of smaller switches, thereby decreasing common mode transients and maximizing switching speed.

Devices n3a, n3b provide symmetric impedance to and from each logic level, and to provide consistency across a wide range of PVT variations. Without n3a, n3b, the output impedance of Q, Qb at a logic-high state is much greater than the output impedance at a logic-low state, and the consistency of the device varies with PVT variations, due to the use of the switching P-channel devices p1a, p1b. The state of the input signals IN, INb determines which of the outputs Q, Qb are connected to ground potential, and thus, which of the devices n3a, n3b are in the conductive state. Thereafter, the output impedance of Q, Qb at a logic-high state is predominantly determined by the transconductance of the corresponding conductive device n3a, n3b. Via the appropriate sizing of these devices n3a-b, relative to devices n4a-b, n6a-b, n8a-b, equivalent high and low impedance characteristics can be achieved. Further, the use of single channel-type devices n3a-b, n4a-b, n6a-b, and n8a-b provides for consistent performance over PVT variations.

Replica biasing is used to control the bias voltages of the H-bridge components. Each transistor n1r, p1r, n2r, n4r, n6ra-b, and n8ra-b in the replica, or reference stack, corresponds to its similarly numbered transistor in each column of the H-bridge. That is, n1r corresponds to n1a, n1b; p1r corresponds to p1a, p1b; and so on.

Transistors n6ra, n6rb, n8ra, n8rb form a current mirror that generates a reference current Ib1+Iref from current source Iref2, Ib1 being the current drawn by n3r, and Iref being the current drawn by the remainder of the reference stack. The voltage drop across current source H-bridge switches n8a, n8b is duplicated across n8ra and n8rb to set the gate voltage ncs. Via appropriate transistor sizing of n8a, n8b compared to n8ra, n8rb, current gain is provided to the H-bridge, as illustrated by the 10*(Ib1−Iref) current flow in each column of the H-bridge, controlled by the state of differential input signals IN, INb.

Reference voltage Vr is used to create the high and low driver reference voltages vrp and vrn, via the operational amplifiers op1, op2, and op3, with resistors R1, R2, and R3 forming a voltage divider network that is consistent over PVT variations. A common standard for low voltage differential signaling calls for an I/O voltage levels of 0-3.3 volts, with maximum and minimum allowed high and low driver levels of 1.4 and 1.0 volts, respectively. In an example embodiment using a nominal reference voltage Vr of 1.2 volts, and resistance values for R1, R2, and R3 of R, R, and 6*R, respectively, the nominal high and low replica levels vrp and vm are 1.37 and 1.03 volts, respectively.

The load L is generally external to the differential transmitter, typically being located in a corresponding differential receiver. The reference resistor Rref accommodates output load variations by maintaining a consistent common-mode output voltage substantially independent of the load L.

FIG. 4 illustrates an example schematic of a differential transmitter with short-circuit and ESD protection in accordance with this invention, as well as transient switching protection.

Triode-connected transistor p0 and capacitive-connected transistor ncap provide isolation between nodes vrpp and vrp so that switching transients do not perturb the replica bias.

Diode-connected transistors n7a,b clamp the drain-source voltage of transistors n8a,b, thereby providing overvoltage protection to these thin-gate transistors.

Diode-connected transistors n5a,b serve a dual purpose. They limit the maximum excursion at the source of transistors n4a,b, thereby limiting current and voltage in the case of short circuited outputs to the I/O supply voltage, as well as providing overvoltage protection to the thin-gate transistors n8a,b. Additionally, they and n5a,b and n9a,b in combination reduce output transients via their gate-source capacitance, which couples the output nodes and the drains of n8a,b.

Transistors p3a,b limit short circuit current though n3a,b in the event of an output being shorted to ground.

Diodes D1,2 limit voltages in the event of an electrostatic discharge (ESD) event at the output pads. Transistors n2a,b and n4a,b also provide ESD protection, as well as latch-up protection.

The foregoing merely illustrates the principles of the invention. It will thus be appreciated that those skilled in the art will be able to devise various arrangements which, although not explicitly described or shown herein, embody the principles of the invention and are thus within the spirit and scope of the following claims.

What is claimed is:

1. A differential transmitter comprising: an H-bridge driver comprising: a pair of substantially identical columns of devices that are configured to receive a pair of differential input signals, each column of the pair of columns being configured to provide an output signal of a pair of differential output signals for coupling to a load that bridges the pair of columns, wherein each column includes a series connection of devices between a first supply voltage and a second supply voltage, and the differential input signals are configured to control a switching device that is at an end of each of the series connection of devices between the first supply voltage and the second supply voltage.

2. The transmitter of claim 1, wherein the switching device comprises a thin-gate transistor.

3. The transmitter of claim 1, further including a pair of drive transistors that are configured to couple the pair of differential output signals to the first supply voltage, parallel to devices in the series connection of devices, so that an output impedance of the differential output signals is substantially determined by a transconductance of the drive transistors.

4. The transmitter of claim 1, further including a replica column of devices that are configured to control bias voltages in the columns of devices of the H-bridge driver.

5. The transmitter of claim 4, further including a triode-connected transistor and a capacitive-connected transistor, operably coupled between the replica column and the H-bridge driver to provide isolation of the replica column from transients in the H-bridge driver.

6. The transmitter of claim 1, further including a pair of diodes operably coupled between the pair of differential output signals and the first supply voltage.

7. The transmitter of claim 1, further including a first diode-connected transistor that is configured to protect the switching device.

8. The transmitter of claim 7, further including a second diode-connected transistor, operably coupled to the first diode-connected transistor that is configured to further protect the switching device.

9. The transmitter of claim 1, wherein the series connection of devices further includes one or more transistors having substantially constant gate voltages.

10. The transmitter of claim 1, wherein the series connection of devices further includes, in series order, a first n-channel device, a first p-channel device, a second n-channel device, a third n-channel device, and a fourth n-channel device that is followed by the switching device.

11. The transmitter of claim 10, wherein the output signal is located between the second n-channel device and the third n-channel device.

12. The transmitter of claim 11, wherein the differential input signals control the first p-channel device in each series connection of devices.

13. The transmitter of claim 11, wherein the first n-channel device, the second n-channel device, the third n-channel device, and the fourth n-channel device are each provided with a substantially constant gate voltage.

14. The transmitter of claim 1, further including a current mirror that is configured to control currents in the columns of devices of the H-bridge driver.

15. The transmitter of claim 14, wherein the switching device is sized relative to the current mirror to provide current gain to the H-bridge driver.

16. The transmitter of claim 1, further including a converter that is configured to convert a single-ended signal to the differential input signals.

17. The transmitter of claim 16, wherein the converter includes a cross-coupled latch.
